(19) United States
(12) Patent Application Publication
(10) Pub. No.: US 2024/0204480 A1
(43) Pub. Date: Jun. 20, 2024

(54) LASER EMITTER AND OPTICAL RANGING APPARATUS

(71) Applicant: DENSO CORPORATION, Kariya-city (JP)

(72) Inventors: MASATO NAKAJIMA, Kariya-city (JP); YOSHIAKI HOASHI, Kariya-city (JP)

(21) Appl. No.: 18/428,298

(22) Filed: Jan. 31, 2024

Related U.S. Application Data
(63) Continuation of application No. PCT/JP2022/028334, filed on Jul. 21, 2022.

(30) Foreign Application Priority Data
Aug. 31, 2021 (JP) 2021-140688

(51) Int. Cl. H01S 5/042; G01S 7/484; G05F 3/20

(52) U.S. Cl. CPC H01S 5/04256; G01S 7/484; G05F 3/20; H01S 5/0428

(57) ABSTRACT

A laser emitter includes a first series connector, a second series connector, a capacitor, and a second switch. The first series connector includes a first coil and a diode connected in series. The diode is connected in forward bias. The first series connector has an end connected to a positive electrode of a DC power supply. The second series connector includes a laser diode and a first switch connected in series. The laser diode is connected in forward bias. The second series connector has an end connected to another end of the first series connector, and has another end connected to a negative electrode of the DC power supply. The capacitor is connected to the second series connector in parallel. The second switch is connected to the second series connector in parallel.

### CROSS REFERENCE TO RELATED APPLICATIONS

The present application is a continuation application of International Patent Application No. PCT/JP2022/028334 filed on Jul. 21, 2022, which designated the U.S. and claims the benefit of priority from Japanese Patent Application No. 2021-140688 filed on Aug. 31, 2021. The entire disclosures of all of the above applications are incorporated herein by reference.

### TECHNICAL FIELD

The present disclosure relates to a laser emitter and an optical ranging apparatus.

### BACKGROUND

A ranging apparatus may measure a distance to an object by emitting a laser beam toward the object and then receiving reflection from the object, and measuring the time from irradiation to optical reception. In order to improve ranging performance, it may be required to irradiate a high-power laser beam.

### SUMMARY

The present disclosure describes a laser emitter and an optical ranging apparatus, each of which includes a first series connector, a second series connector, and a capacitor.

### BRIEF DESCRIPTION OF DRAWINGS

Objects, features and advantages of the present disclosure will become more apparent from the following detailed description made with reference to the accompanying drawings. In the drawings:

FIG. 1 illustrates a structure of an optical ranging apparatus according to a first embodiment;

FIG. 2 illustrates a circuitry structure of a laser emitter according to the first embodiment;

FIG. 3 is a flowchart of a light emission process;

FIG. 4 is a timing chart of a light emission process;

FIG. 5 is a flowchart of a light emission process according to another embodiment; and

FIG. 6 is a timing chart of light emission processing according to the other embodiment.

### DETAILED DESCRIPTION

In order to irradiate a high-power laser beam of an optical ranging apparatus, it may be necessary to apply a high voltage to the laser diode that emits the laser beam.

A booster circuit may be adopted to apply a high voltage to the laser diode. A laser emitter includes a chopper booster circuit. In the chopper booster circuit, the capacitor is charged by repeatedly executing switchover between a conductive state and a non-conductive state of a coil. As a result, the voltage of the capacitor is raised. In the laser emitter, when the voltage of the capacitor reaches a target voltage, a switch connected to the laser diode in series is turned on so that the laser diode may be in a conductive state to emit light. The charge stored in the capacitor is discharged through the laser diode, therefore, the voltage decreases across the capacitor.

However, a signal for turning on the switch connected in series to the laser diode may not be provided. In this case, since the capacitor is not discharged, the voltage of the capacitor continues to rise beyond the target voltage. Thus, an overvoltage may be applied to, for example, the laser diode and the capacitor.

According to a first aspect of the present disclosure, a laser emitter includes a first series connector, a second series connector, a capacitor, and a second switch. The first series connector includes a coil and a diode being connected in series. The diode is connected in forward bias to a DC power supply. The first series connector has an end being connected to a positive electrode of the DC power supply. The second series connector includes a laser diode and a first switch being connected in series. The laser diode is connected in forward bias to the DC power supply. The second series connector has an end being connected to another end of the first series connector and has another end being connected to a negative electrode of the DC power supply. The capacitor is connected to the second series connector in parallel. The second switch is connected to the second series connector in parallel.

According to such a structure described above, even though an on-state signal cannot be provided to the first switch, it is possible to inhibit a situation of applying an overvoltage to the laser diode since the charge in the capacitor is discharged through the second switch by turning on the second switch that is connected in parallel to the second series connector.

According to a second aspect of the present disclosure, an optical ranging apparatus includes a laser emitter, a light receiver, and a calculator. The laser emitter includes a first series connector, a second series connector, a capacitor, and a second switch. The first series connector includes a coil and a diode being connected in series. The diode is connected in forward bias to a DC power supply. The first series connector has an end being connected to a positive electrode of the DC power supply. The second series connector includes a laser diode and a first switch being connected in series. The laser diode is connected in forward bias to the DC power supply. The second series connector has an end being connected to another end of the first series connector and has another end being connected to a negative electrode of the DC power supply. The capacitor is connected to the second series connector in parallel. The second switch is connected to the second series connector in parallel. The light receiver receives reflection light reflected by an object to which laser light is emitted from the laser diode. The calculator calculates a distance to the object based on a time duration from a moment at which the laser diode emits the laser light to a moment at which the light receiver receives the reflection light.

According to such a structure, since the laser emitter included in the optical ranging apparatus can inhibit the application of an overvoltage to the laser diode, it is possible to enhance the reliability of the optical ranging apparatus.

### First Embodiment

The following describes an optical ranging apparatus 100 according to a first embodiment.

### Structure of Optical Ranging Apparatus

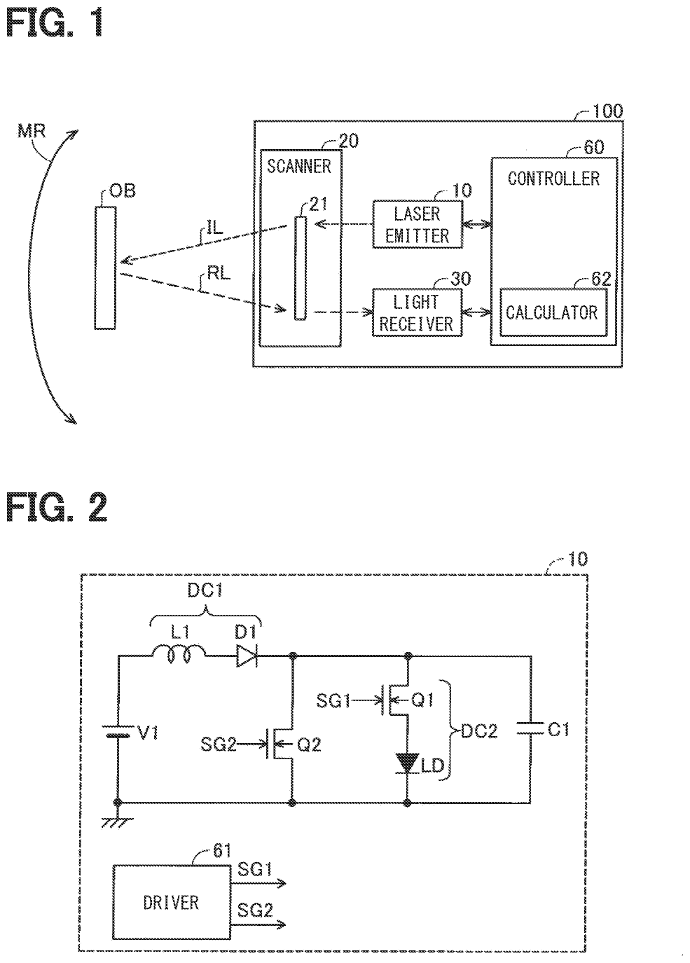

The optical ranging apparatus 100 illustrated in FIG. 1 detects a distance to an object OB by emitting laser light IL and receiving reflection light RL reflected by the object OB. The optical ranging apparatus 100 may be adapted to, for example, a vehicle. In the present embodiment, the optical ranging apparatus 100 is a Light Detection And Ranging (LiDAR) apparatus. The optical ranging apparatus 100 includes a laser emitter 10, a scanner 20, a light receiver 30 and a controller 60. The laser light emitter 10 emits laser light IL for ranging. The ranging may also be referred to as distance measurement. The laser light IL may also be referred to as a laser beam.

The controller 60 includes a computer including, for example, a CPU and a memory. The controller 60 controls the operations of the laser emitter 10, the scanner 20 and the light receiver 30. The controller 60 further includes a calculator 62. The calculator 62 calculates the distance to the object OB. The calculator 62 may be operated by the CPU executing a program stored in the memory, or may be operated by an electronic circuit.

The laser emitter 10 includes a laser diode LD for emitting pulsed laser light IL. The laser light IL emitted from the laser diode LD is collimated by a collimating lens (not shown) and enters the scanner 20.

The scanner 20 scans the laser light IL within a predetermined measurement range MR. The scanner 20 includes a mirror 21 and a rotary solenoid (not shown). The mirror 21 reflects the laser light IL, and the rotary solenoid drives the mirror 21. The rotary solenoid repeats a normal rotation and a reverse rotation within a predetermined angle range, so that the laser light IL is scanned within the measurement range MR.

The light receiver 30 receives reflection light RL reflected by the object OB to which the laser light IL is emitted from the laser diode LD. The light receiver 30 outputs a detection signal according to the intensity of the received light to the calculator 62.

The calculator 62 calculates the distance to the object OB by adopting the detection signal received from the light receiver 30. The calculator 62 calculates a distance to the object OB by adopting time of flight (TOF) being a time measured from a moment where the laser light is emitted until a moment where the reflection light is received.

### Circuitry Structure of Laser Emitter

As shown in FIG. 2, the laser emitter 10 includes a DC power supply V1, a first series connector DC1, a second series connector DC2, a capacitor C1, a second switch Q2, and a driver 61. The first series connector DC1 includes a coil L1 and a diode D1 connected in forward bias to the DC power supply V1. The coil L1 and the diode D1 are connected in series. The inductance of the coil L1 is about 10 μH or more and 100 μH or less. An end of the first series connector DC1 is connected to the positive electrode of the DC power supply V1. In the present embodiment, the coil L1 and the diode D1 are connected in the order of the coil L1 and the diode D1 from the positive electrode to the negative electrode of the DC power supply V1. The second series connector DC2 includes a laser diode LD and a first switch Q1 being connected in series. The laser diode LD is connected in forward bias to the DC power supply V1. An end of the second series connector DC2 is connected to the other end of the first series connector DC1, and the other end of the second series connection body is connected to the negative electrode of the DC power supply V1. In the present embodiment, the first switch Q1 and the laser diode LD are connected in the order of the first switch Q1 and the laser diode LD from the positive electrode to the negative electrode of the DC power supply V1. The capacitor C1 is connected to the second series connector DC2 in parallel. The capacitance of the capacitor C1 is approximately several thousand picofarads (pF). The second series connector DC2 is connected to the second switch Q2 in parallel. In the present embodiment, each of the first switch Q1 and the second switch Q2 is an N-channel insulated gate field effect transistor (IGFET). The driver 61 includes an electronic circuit. The gate of the first switch Q1 receives a first gate signal SG1 output from the driver 61. The gate of the second switch Q2 receives a second gate signal SG2 output from the driver 61. The negative electrode of the DC power supply V1 is connected to the ground.

In the first series connector DC1, the diode D1 and the coil L1 may be connected in the order of the diode D1 and the coil L1 from the positive electrode to the negative electrode of the DC power supply V1. In the second series connector DC2, the laser diode LD and the first switch Q1 may be connected in the order of the laser diode LD and the first switch Q1 from the positive electrode to the negative electrode of the DC power supply V1. Each of the first switch Q1 and the second switch Q2 may be a field-effect transistor (FET) other than IGFET. For example, the FET may be a high electron mobility transistor (HEMT) using gallium nitride (GaN). The HEMT may also be referred to as a heterostructure field-effect transistor (HFET).

Furthermore, each of the first switch Q1 and the second switch Q2 may be a bipolar transistor or may be configured by an integrated circuit. Each of the first switch Q1 and the second switch Q2 may be a P-channel IGFET.

### Driving Method of Laser Emitter

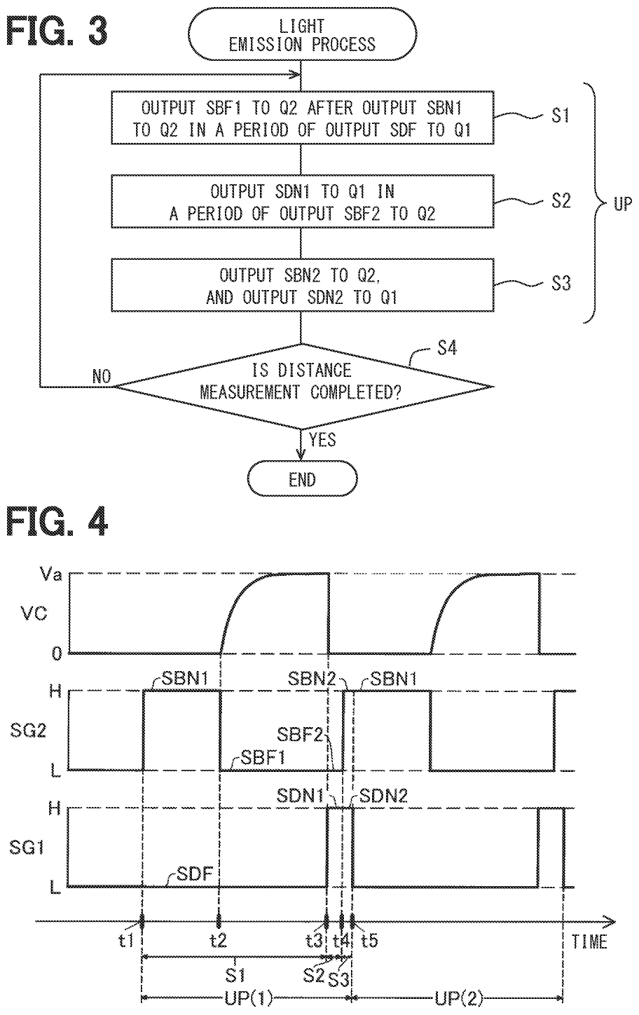

The driver 61 executes a light emission process as shown in FIG. 3 in conjunction with a ranging process executed by the controller 60 for measuring a distance to the object OB. In S1, in a period during which the driver 61 outputs a drive-off signal SDF to the first switch Q1, the driver 61 outputs a first boost-off signal SBF1 to the second switch Q2 after the driver 61 outputs a first boost-on signal SBN1 to the second switch Q2.

As illustrated in FIG. 4, in S1, the first gate signal SG1 at a low level L as the drive-off signal SDF is provided to the gate of the first switch Q1 from time t1 to time t3. Then, the second gate signal SG2 at a high level H as the first boost-on signal SBN1 is provided to the gate of the second switch Q2 from time t1 to time t2, and then the second gate signal SG2 at a low level L as the first boost-off signal SBF1 is provided to the gate of the second switch Q2 from the time t2 to time t3.

During the period from the time t1 to the time t2, the second switch Q2 is in an on state, so a current flows through the coil L1. At the time t2, when the second switch Q2 is turned off, the current path through the second switch Q2 is cut off, so that the current flows through the coil L1 according to the inductance of the coil L1. Since the charge is accumulated in the capacitor C1 by the current flowing through the coil L1, the capacitor voltage VC rises to a target voltage Va higher than the DC voltage of the DC power supply V1. The capacitor voltage VC is a voltage across the capacitor C1. The DC voltage of DC power supply V1 is around several tens of volts, and the target voltage Va is around several tens to several hundreds of volts.

In S2 as shown in FIG. 3, in a period during which the driver 61 outputs a second boost-off signal SBF2 to the second switch Q2, the driver 61 outputs a first drive-on signal SDN1 to the first switch Q1.

In S2, the first gate signal SG1 at a low level as the second boost-off signal SBF2 is output to the second switch Q2 from the time t3 to time t4 as shown in the time t3 to t4. The first gate signal SG1 at a high level H as the first drive-on signal SDN1 is output to the first switch Q1. At the time t3, when the first switch Q1 is turned on, a voltage corresponding to the target voltage Va is applied to the laser diode LD.

The charge accumulated in the capacitor C1 moves to the ground via the first switch Q1 and the laser diode LD, which are in an on state. Accordingly, the laser diode LD emits light in a period corresponding to the charge accumulated in the capacitor C1. In other words, the laser diode LD emits the pulsed laser light IL. The pulse width of the laser light IL is about 1 nanosecond (ns) or more and 10 ns or less. The optical output of the laser light IL is approximately several 10 watts (W) or more and several 100 W or less. The capacitor C1 is discharged, and the capacitor voltage VC becomes 0 volt (V).

In S3 as shown in FIG. 3, the driver 61 outputs a second boost-on signal SBN2 to the second switch Q2, and outputs a second drive-on signal SDN2 to the first switch Q1. In S3, the driver 61 outputs the second signal SG2 at a high level H as the second boost-on signal to the gate of the second switch Q2 and outputs the first gate signal SG1 at a high level H as the second drive-on signal SDN2 to the first switch Q1 from the time t4 to time t5 as shown in FIG. 4. As a result, both the first switch Q1 and the second switch Q2 are turned on. S1 to S3 are executed within the unit period UP. The time of the unit period UP is approximately several microseconds (μs).

In S3 as illustrated in FIG. 3, in a case where the controller 60 completes the ranging process, in other words, a distance measurement process (S4: YES), the light emission process is completed. On the other hand, in a case where the controller 60 does not complete the ranging process (S4: NO), the process is shifted to S1, and S1 to S3 are repeatedly executed. The completion of the light emission process is not limited to at a time after S3. In a case where the controller 60 completes the ranging process, the light emission process is completed regardless of which of S1 to S3 is executed.

When the light emission process is continued, as shown in FIG. 4, S1 in the subsequent unit period UP is executed from time t5. That is, after S3, S1 in a subsequent unit period UP is executed continuously. By executing S3 before S1, it is possible to reduce charging that does not contribute the boosting of the voltage across the capacitor C1. In a case where, after S2, the first switch Q1 is turned off and then the second switch Q2 is turned on, the capacitor C1 will be charged as the first switch Q1 is turned off. Subsequently, as the second switch Q2 is turned on, the capacitor C1 is discharged via the second switch Q2. According to the present embodiment, it is possible to reduce the charging of the capacitor C1 that does not contribute to the boosting of the voltage across the capacitor C1 by turning on the second switch Q2 and then turning off the first switch Q1. The subsequent unit period UP corresponds to UP(2) as illustrated in FIGS. 4.

S1 and S2 are executed continuously, and S2 and S3 are executed continuously. That is, the voltage level of the second gate signal SG2 is not switched between the first boost-off signal SBF1 and the second boost-off signal SBF2. The voltage level of the first gate signal SG1 is not switched between the first drive-on signal SDN1 and the second drive-on signal SDN2. Similarly, S3 and S1, which is in the subsequent unit period UP, are executed continuously. That is, the voltage level of the second gate signal SG2 is not switched between the second boost-on signal SBN2 and the first boost-on signal SBN1.

The first drive-on signal SDN1 may not be provided to the gate of the first switch Q1 due to a fault in the controller 60 or the driver 61. In the present embodiment, even though the first drive-on signal SDN1 is not provided, when the first boost-on signal SBN1 is provided in the subsequent unit period UP, the capacitor C1 is discharged by a current path through the second switch Q2 in the on state. Therefore, it is possible to avoid a situation in which an overvoltage is applied to the laser diode LD.

According to the embodiment described above, the laser emitter 10 includes a first series connector DC1, a second series connector DC2, a capacitor C1 and a second switch Q2. Even though the first drive-on signal SDN1 is not provided to the first switch Q1 due to a fault, when the first boost-on signal SBN1 is provided to the second switch Q2 being connected in parallel to the second series connector DC2, it is possible to inhibit the application of an overvoltage to the laser diode LD since the electric charge of the capacitor C1 is discharged through the second switch Q2.

The driver 61 executes S1 once and S2 once in the unit period UP. In S1, in a period during which the driver 61 outputs a drive-off signal SDF to the first switch Q1, the driver 61 outputs a first boost-off signal SBF1 after the driver 61 outputs a first boost-on signal SBN1 to the second switch Q2. In S2, in a period during which the driver 61 outputs a second boost-off signal SBF2 to the second switch Q2, the driver 61 outputs a first drive-on signal SDN1 to the first switch Q1. Thereby, the capacitor voltage VC can be boosted by S1. In S2, when the first drive-on signal SDN1 is normally provided, the second switch Q2 is turned off and the first switch Q1 is turned on. Thus, the electric charge in the capacitor C1 flows to the laser diode LD and the laser diode LD emits light. Even though the first drive-on signal SDN1 is not provided in S2, when the first boost-on signal SBN1 is provided in S1 of the subsequent unit period UP, the electric charge accumulated in the capacitor C1 is discharged through the second switch Q2 in the on state. Therefore, it is possible to inhibit a situation in which an overvoltage is applied to the laser diode LD.

The driver 61 executes S3 at a timing after S2 executed in the unit period UP and before S1 executed in the subsequent unit period UP. In S3, the driver 61 outputs the second boost-on signal SBN2 to the second switch Q2 and the second drive-on signal SDN2 to the first switch Q1. In the light emission process, it is possible to reduce the charging of the capacitor C1 that does not contribute to the raising of the voltage. The raising of the voltage may also be referred to as boosting of the voltage.

The optical ranging apparatus 100 includes the light receiver 30 and the calculator 62. The light receiver 30 receives the reflection light RL reflected by the object OB to which the laser light IL emitted from the laser diode LD. The calculator 62 calculates the distance to the object OB by adopting a time duration from a moment of emitting the laser light L to a moment of receiving the reflection light RL. It is possible to provide the optical ranging apparatus 100 with enhanced reliability by using the laser emitter 10.

### Other Embodiments

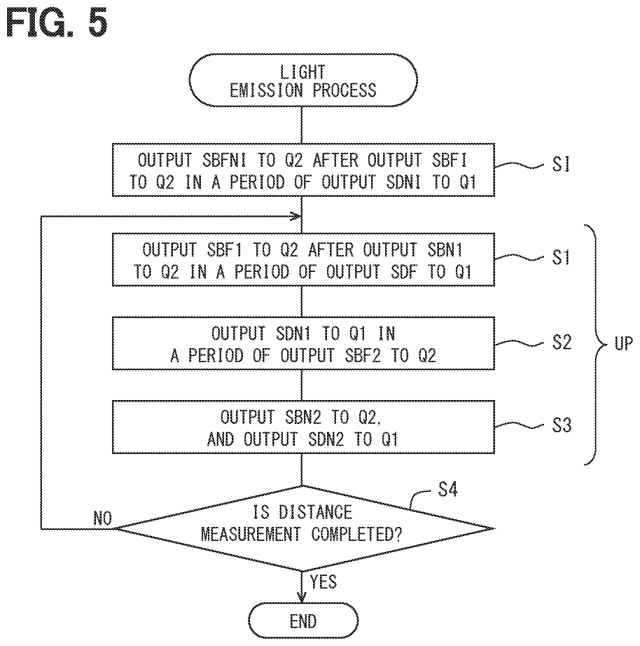

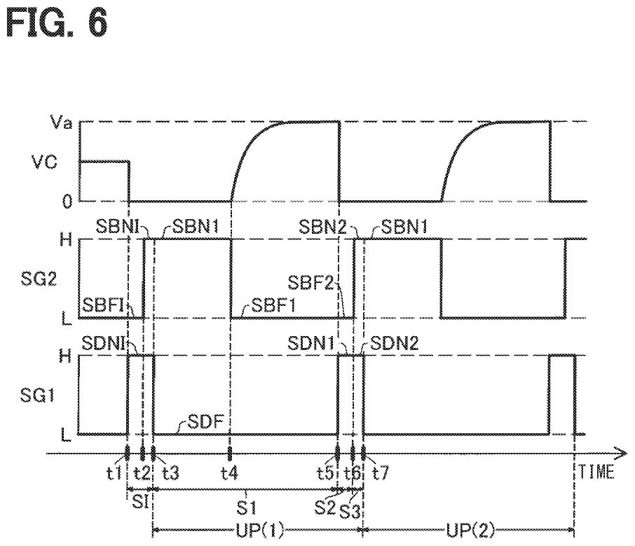

In the first embodiment, when the light emission process is started, S1 to S3 are repeatedly executed. However, as shown in FIG. 5 being related to another embodiment, S1 to S3 may be repeatedly executed after the light emission process is started and SI is executed. In the present disclosure, SI corresponds to an initial mode; S1 corresponds to a first mode; S2 corresponds to a second mode; and S3 corresponds to a third mode. Each of S1 to S3 illustrated in FIG. 5 are identical to S1 to S3 according to the first embodiment. In the light emission process according to the present embodiment, an initial boost-on signal SBN1 is output to the second switch Q2 after an initial boost-off signal SBFI is output to the second switch in SI. As shown in FIG. 6, the first gate signal SG1 in the high level H as the initial drive-on signal SDNI is provided to the first switch Q1 from the time t1 to t3. In a time duration from the time t1 to t2, the second gate signal SG2 in the high level H as the initial boost-on signal SBNI is output to the second switch Q2 after the second gate signal SG2 in the low level L as the initial boost-off signal SBFI is output to the second switch Q2. As a result, if the capacitor C1 has been charged due to the previous light emission process, the capacitor C1 is discharged via the first switch Q1 and the laser diode LD. Thereafter, S1 to S3 are repeated as in the first embodiment.

The present disclosure should not be limited to the embodiments or modifications described above, and various other embodiments may be implemented without departing from the scope of the present disclosure. For example, the technical features in each embodiment corresponding to the technical features in the form described in the summary may be used to solve some or all of the above-described problems, or to provide one of the above-described effects. In order to achieve a part or all, replacement or combination can be appropriately performed. In addition, as long as a technical feature is not described as essential in the present specification, the technical feature may be deleted as appropriate.

The driver and the technique according to the present disclosure may be achieved by a dedicated computer provided by constituting a processor and a memory programmed to execute one or more functions embodied by a computer program. Alternatively, the driver and the method described in the present disclosure may be realized by a dedicated computer provided by configuring a processor with one or more dedicated hardware logic circuits. Alternatively, the driver and the method described in the present disclosure may be implemented by one or more special purpose computer, which is configured as a combination of a processor and a memory, which are programmed to perform one or more functions, and a processor which is configured with one or more hardware logic circuits. The computer program may be stored, as instructions to be executed by a computer, in a tangible non-transitory computer-readable medium.

The present disclosure has been described based on examples, but it is understood that the present disclosure is not limited to the examples or structures. The present disclosure encompasses various modifications and variations within the scope of equivalents. In addition, various combinations and forms, and further, other combinations and forms including only one element, or more or less than these elements are also within the scope and the scope of the present disclosure.

The process of the flowchart or the flowchart described in this application includes a plurality of sections, and each section is expressed as, for example, S1. Each section may be divided into several subsections, while several sections may be combined into one section. Furthermore, each section thus configured may be referred to as a device, module, mode, or means.

What is claimed is:

1. A laser emitter comprising:
a first series connector including a coil and a diode being connected in series, the diode being connected in forward bias to a DC power supply, the first series connector having an end being connected to a positive electrode of the DC power supply;
a second series connector including a laser diode and a first switch being connected in series, the laser diode being connected in forward bias to the DC power supply, the second series connector having
an end being connected to another end of the first series connector, and
another end being connected to a negative electrode of the DC power supply;
a capacitor being connected to the second series connector in parallel; and
a second switch being connected to the second series connector in parallel.

2. The laser emitter according to claim 1, further comprising:
a driver configured to control the laser emitter by executing a first mode once and a second mode once in a unit period;
the first mode is a mode for charging the capacitor, in which the driver outputs a first boost-on signal to the second switch and then outputs a first boost-off signal to the second switch in a period during which the driver outputs a drive-off signal to the first switch;
the second mode is a mode for causing the laser diode to emit light, in which the driver outputs a first drive-on signal to the first switch in a period during which the driver outputs a second boost-off signal to the second switch; and
the first boost-on signal causes the second switch being turned on, the first boost-off signal causes the second switch being turned off, the drive-off signal causes the first switch being turned off, the first drive-on causes the first switch being turned on, and the second boost-off signal causes the second switch being turned off.

3. The laser emitter according to claim 2, wherein:
the driver is further configured to control the laser emitter by executing the first mode and the second mode in every unit period, and the second mode is executed after the first mode;
the driver is further configured to execute a third mode at a timing after the second mode executed in a unit period and before the first mode executed in a subsequent unit period being subsequent to the unit period;
the third mode is a mode in which the driver outputs a second boost-on signal to the second switch and outputs a second drive-on signal to the first switch; and
the second boost-on signal causes the second switch being turned on, and the second drive-on signal causes the first switch being turned on.

4. An optical ranging apparatus comprising:
a laser emitter including
a first series connector including a coil and a diode being connected in series, the diode being connected in forward bias to a DC power supply, the first series connector having an end being connected to a positive electrode of the DC power supply,
a second series connector including a laser diode and a first switch being connected in series, the laser diode being connected in forward bias to the DC power supply, the second series connector having
an end being connected to another end of the first series connector, and
another end being connected to a negative electrode of the DC power supply,
a capacitor being connected to the second series connector in parallel, and
a second switch being connected to the second series connector in parallel;
a light receiver configured to receive reflection light reflected by an object to which laser light is emitted from the laser diode; and
a calculator configured to calculate a distance to the object based on a time duration from a moment at which the laser diode emits the laser light to a moment at which the light receiver receives the reflection light.
